(19) United States
(12) Patent Application Publication
(10) Pub. No.: US 2016/0201185 A1
(43) Pub. Date: Jul. 14, 2016

(54) MASK DEVICE AND METHOD FOR ASSEMBLING THE SAME

(71) Applicants: BOE TECHNOLOGY GROUP CO., LTD., Beijing (CN); ORDOS YUANSHENG OPTOELECTRONICS CO., LTD., Ordos (CN)

(72) Inventors: Shanshan BAI, Beijing (CN); Fengli JI, Beijing (CN); Minghua XUAN, Beijing (CN)

(73) Assignees: ORDOS YUANSHENG OPTOELECTRONICS CO., LTD., Ordos (CN); BOE TECHNOLOGY GROUP CO., LTD., Beijing (CN)

(21) Appl. No.: 14/744,680

(22) Filed: Jun. 19, 2015

(30) Foreign Application Priority Data
Jan. 14, 2015 (CN) 201510019170.9

(51) Int. Cl. C23C 14/04; H01L 51/56; B23K 31/02

(52) U.S. Cl. CPC C23C 14/042; B23K 31/02; H01L 51/56

(57) ABSTRACT

Disclosed are a mask device and a method for assembling the same. The mask device may include a frame; and a mask plate arranged within the frame. The frame may include a first frame and a second frame which are fixed together one on another. The first frame may be made of a shape memory alloy; while the second frame may be made of a metal material whose thermal expansion coefficient is smaller than a predetermined value. And the mask plate is welded to the first frame.

### CROSS-REFERENCE TO RELATED APPLICATION

The present application claims a priority of the Chinese patent application No. 201510019170.9 filed on Jan. 14, 2015, which is incorporated herein by reference in its entirety.

### FIELD OF THE INVENTION

The present disclosure relates to a field of mask technology, in particular to a mask device and a method for assembling the same.

### DESCRIPTION OF THE PRIOR ART

As for Organic Light-Emitting Diode (OLED) technology, mask plate used for vacuum evaporation is one of significant techniques. Manufacturing cost and product quality largely depend on a quality of mask plate. A Fine Metal Mask (FMM) used as a mask plate for evaporating OLED is one of most important mask plates. The FMM is used for evaporating a material of a light emitting layer. Display effect of screen largely depends on the quality of FMM. FMM is usually made of INVAR metal and has a very small thickness (about 30-50 um). In the process of evaporation, FMM is attached to a surface of an evaporation substrate. And it is challenging to retain a high position precision. Therefore it is common to weld FMM to a metal frame (usually INVAR frame) by laser welding, prior to an actual usage. When a first FMM strip is welded to the frame, a counter force C1 is imposed on two opposite ends of the frame first. And then a force F for tension is imposed on the two ends of the FMM strip, and the FMM strip is welded to the frame. Next a second FMM strip is welded, and the counter force is reduced to C2=C1−F. And respective FMMs to be welded are imposed with less counter force sequentially. Therefore, the counter force has to be adjusted for each FMM strip to be welded. As a result, not only the process is complicated, but also it is hard to determine force magnitude. Moreover, the above causes the force imposed on respective FMM strips are different, which deteriorates uniformity of opening shapes for respective FMMs.

### SUMMARY OF THE INVENTION

The technical problem to be solved is to simplify mask plate assembly process, and to improve uniformity of opening shapes for the mask plate.

In order to achieve the above objective, disclosed by the present disclosure are a mask device and a method for assembling the same.

In an aspect of the present disclosure, a mask device is provided. The mask device may include: a frame; and a mask plate arranged within the frame. The frame may include a first frame and a second frame which are fixed together one on another. The first frame may be made of a shape memory alloy; while the second frame may be made of a metal material whose thermal expansion coefficient is smaller than a predetermined value. And the mask plate may be welded to the first frame.

Alternatively, the shape memory alloy may be a nickel titanium alloy.

Alternatively, the second frame may be made of stainless steel or an invar alloy.

Alternatively, the first frame may be of 0.1-10 mm thickness, while the second frame may be of a 10-30 mm thickness.

Alternatively, the first frame and the second frame may be provided with pairs of spiral registration holes, through which the first frame and the second frame are fixed to each other by using bolts.

Alternatively, the mask plate may include a plurality of light-shielding metal stripes spaced from each other.

Alternatively, the mask plate may be a Fine Metal Mask (FMM) for Organic Light-Emitting Diode (OLED) evaporation.

According to another aspect of the present disclosure, a method for assembling a mask device is provided. The method may include: providing a first frame, which is made of a shape memory alloy; providing a second frame, which is made of a metal material whose thermal expansion coefficient is smaller than a predetermined value; imposing a constant force onto two opposite ends of the first frame, so as to enable the two opposite ends of the first frame to be contracted inward and thereby deformed; welding a mask plate to the first frame; subsequent to the welding, stopping imposing the constant force onto the two opposite ends of the first frame; heating the first frame, so as to restore the first frame to be in an original form; and fixing the first frame welded with the mask plate onto the second frame.

Alternatively, the mask plate may include a plurality of light-shielding metal stripes spaced from each other; and the step of welding the mask plate to the first frame may include: welding two ends of each of the light-shielding metal stripes on two opposite ends of the first frame, respectively.

Alternatively, an actual length of the light-shielding metal stripe may be X % less than a design value; and the constant force may meet the following condition: a deformation magnitude generated when the two opposite ends of the first frame are contracted inward is equal to X % of the design value of the light-shielding metal stripe.

Alternatively, the step of heating the first frame, so as to restore the first frame to be in the original form may include: heating the first frame by using hot metal wires.

Alternatively, in the step of heating the first frame, so as to restore the first frame to be in the original form, the first frame may be heated at a temperature of 100-200° C. when the first frame is made of a nickel titanium alloy.

The above technical solutions of the present disclosure can achieve the following advantageous effects, including:

Compared with conventional structure of a frame of a mask plate in the related arts in which stainless steel or invar alloy has been used, in the mask device provided by the present disclosure, a shape memory alloy having a shape memory function is used for the frame of the mask plate. Therefore, in the process of welding and assembling mask plate, there is needless to adjust the counter force imposed, and a constant force is always imposed on the frame made of the shape memory alloy. After completion of welding and assembling the mask plate, the counter force is stopped imposing and the frame made of the shape memory alloy is heated, so as to enable the frame made of the shape memory alloy to restore its original shape before it is deformed. The assembly method can simplify the assembly process for the mask device greatly, improve the quality of the mask plate, and improve a production efficiency and yield, which is significant to the actual production and improvement of yield.

### BRIEF DESCRIPTION OF THE DRAWINGS

In order to illustrate embodiments of the present disclosure or technical solutions in the prior art more clearly, drawings to be used for description of the embodiments or the prior art will be introduced briefly. Obviously, the following drawings only show some embodiments of the present disclosure. The skilled in the art may also obtain other drawings based on these drawings without any creative labor.

FIG. 1 is a diagram illustrating a structure of a mask device according to embodiments of the present disclosure; and

FIGS. 2-6 are diagrams illustrating methods for assembling the mask device according to embodiments of the present disclosure.

### DETAILED DESCRIPTION OF THE PREFERRED EMBODIMENTS

Embodiments of the present disclosure are further described in conjunction with the drawings and examples hereinafter. The following examples are only for describing the present disclosure, and not meant to limit the scope of the present disclosure.

To make the objects, solutions and advantages of the present disclosure more obvious, technical solutions of the embodiments of the present disclosure will be illustrated in detail in the following in conjunction with the drawings of the embodiments. Apparently, the described embodiments are only some but not all of the embodiments of the present disclosure. All the other embodiments obtained by those skilled in the art based on the described embodiments of the present disclosure fall within the scope of protection of the present disclosure.

Technical terms or scientific terms used here should have a common meanings understood by those ordinary skilled in the art. Words such as “first” and “second” used in the specification and the claims of this patent application do not indicate any order, quantity or importance, and are only used to distinguish different components, unless defined otherwise. Similarly, words such as “one” and “a/an” do not indicate any numeral limitation either, but at least one existing. Words such as “connected to” or “connected with” do not limited to physical or mechanical connection necessarily, but can include electrical connection, either direct or indirect. Words such as “upper”, “lower”, “left” and “right” only used to indicate the relative position relation, and if the absolute position of the described object changes, the relative position relation changes accordingly.

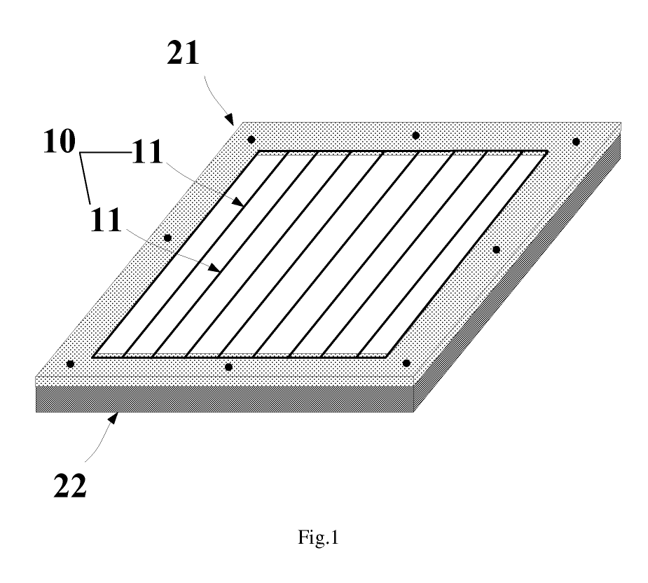

As shown in FIG. 1, which is a diagram illustrating a structure of a mask device according to an embodiment of the present disclosure, the mask device includes a frame and a mask plate 10 arranged within the frame. The frame includes a first frame 21 and a second frame 22 which are fixed together one on another. The first frame 21 is made of a shape memory alloy, while the second frame 22 is made of a metal material whose thermal expansion coefficient is smaller than a predetermined value. And the mask plate is welded to the first frame 21.

Alternatively, the shape memory alloy is a nickel titanium alloy. It can be appreciated that the shape memory alloy can be other kinds of memory alloy, as long as the shape memory alloy has a deformation recovery function. In other words, after the shape memory alloy is deformed due to an external force, it is able to restore its original shape before it is deformed.

The metal material with a smaller thermal expansion coefficient is not inclined to be deformed. Alternatively, the second frame is made of stainless steel or an invar alloy. Stainless steel or the invar alloy is of a smaller thermal expansion coefficient.

In embodiments of the present disclosure, the first frame 21 is relatively thinner, while the second frame 22 is relatively thicker. Alternatively, the first frame is of a 0.1-10 mm thickness, while the second frame is of a 10-30 mm thickness.

Namely the mask plate according to embodiments of the present disclosure is a two-layer structure. Specifically, the upper layer frame (the first frame 21) is made of the shape memory alloy having a shape memory function, which is of a thin thickness and is used for assembling and welding the mask plate 10. The lower layer frame (the second frame 22) is made of a metal material having a smaller thermal expansion coefficient and is thicker, which is used to secure the mask plate 10 and prevent the mask plate after its welding assembly from being deformed.

Alternatively, the first frame 21 and the second frame 22 are provided with pairs of spiral registration holes, through which the first frame 21 and the second frame 22 are fixed to each other by using bolts. In certain embodiments of the present disclosure, three spiral registration holes are provided on each of four edges of the first frame 21 and the second frame 22. It can be appreciated that the first frame 21 and the second frame 22 might be fixed in other manners.

In embodiments of the present disclosure, the mask plate 10 includes a plurality of light-shielding metal stripes 11 spaced from each other. It can be appreciated that the mask plate 10 may well be other kinds of patterns.

Alternatively, in embodiments of the present disclosure, the mask plate 10 is an FMM mask plate for OLED evaporation, which is used for evaporating light emitting material.

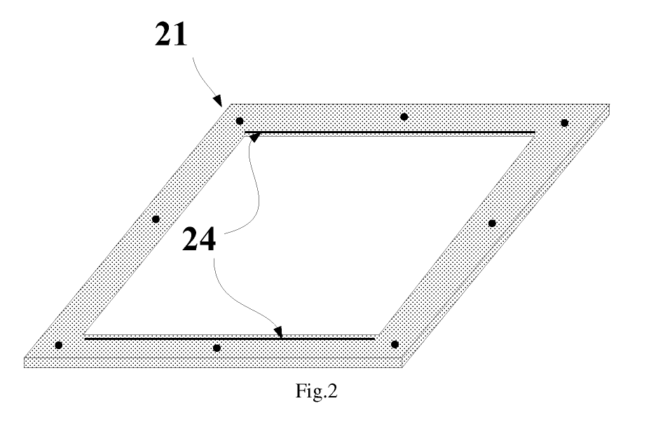

Next referring to FIGS. 2-5, the method for assembling the mask device in above embodiments may include the following step:

Step S101, as shown in FIG. 2, providing a first frame 21, which is made of a shape memory alloy;

Step S102, providing a second frame, which is made of a metal material whose thermal expansion coefficient is smaller than a predetermined value;

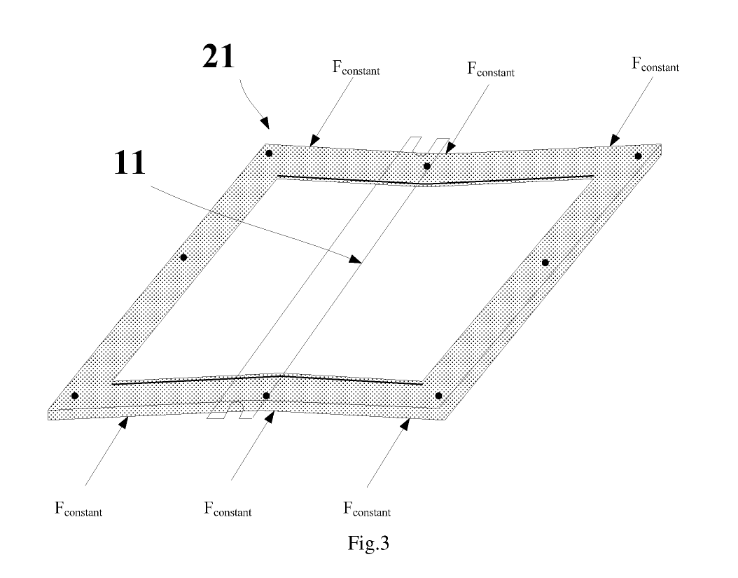

Step S103, as shown in FIG. 3, imposing a constant force F_{constant} onto two opposite ends of the first frame 21, so as to enable the two opposite ends of the first frame to be contracted inward and thereby deformed;

Step S104, as shown in FIG. 3, welding a mask plate to the first frame 21;

In the present embodiment, the mask plate includes a plurality of light-shielding metal stripes spaced from each other; in actual welding, two ends of the light-shielding metal stripe 11 may be welded onto welding wires 24 on two opposite ends of the first frame 21 directly, without stretching light-shielding metal stripe 11. Specifically, the plurality of light-shielding metal stripes 11 may be welded on a basis of stripe by stripe, or may be welded simultaneously;

Step S105, stopping imposing the constant force F_{constant} onto the first frame 21, subsequent to the welding;

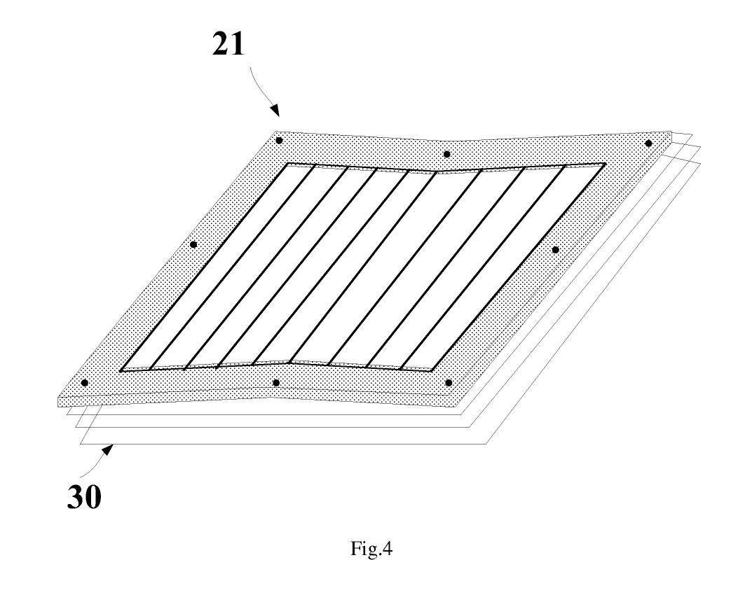

Step S106, as shown in FIG. 4, heating the first frame 21, so as to restore the first frame 21 to be in an original form;

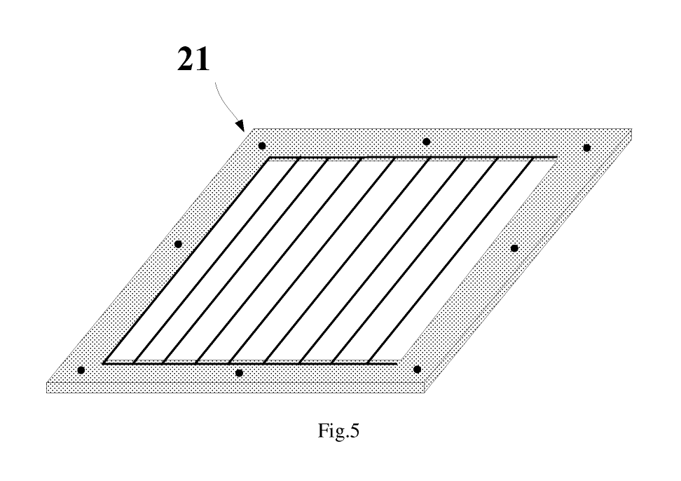

In embodiments of the present disclosure, the first frame 21 may be heated by using hot metal wires 30, so as to restore the first frame 21 to its original shape. The first frame may be heated at a temperature of 100-200° C. when the first frame 21 is made of a nickel titanium alloy, such that the first frame 21 may be restored to its original shape, as shown in FIG. 5;

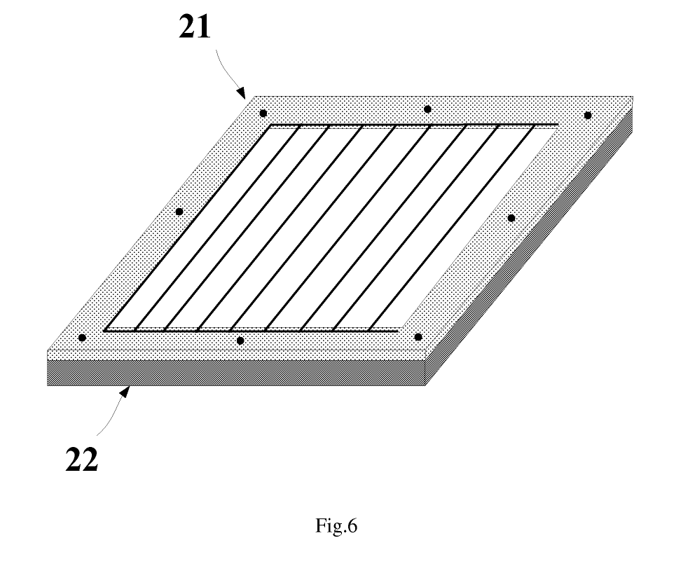

Step S107, as shown in FIG. 6, fixing the first frame 21 welded with the mask plate onto the second frame 22.

Alternatively, in embodiments of the present disclosure, the first frame 21 is made of a nickel titanium alloy, which has a shape memory function and may be plastically deformed due to an external force under a normal temperature. Specifically, an austenite in the alloy is transformed, caused by tension, into a martensite; on the other hand, after heat process, an inverse transformation happens, i.e., from the martensite back to the austenite, so as to restore its original shape as memorized (shape prior to deformation at the low temperature). A nickel titanium alloy has a deformation magnitude that can be completely restored of 6%-8%, while the deformation magnitude for a common mask plate design is only 0.0Y %. Therefore, it is safe that the first frame 21 can restore its original shape.

In embodiments of the present disclosure, when the mask plate includes a plurality of light-shielding metal stripes 11 spaced from each other, due to light-shielding metal stripes 11 being quite long and thin (generally 30-40 um), the mask plate plummets in the middle to deform itself, under the effect of gravity. Therefore, in an actual manufacture, an actual length of the light-shielding metal stripes 11 are X % shorter than a design value. After welding the light-shielding metal stripes 11 is completed and the first frame 21 recovers from its deformation, the light-shielding metal stripes 11 remain tight and straight under tension, and a strain rate for lengthening is X %. In this way, a length of each grid-like light-shielding metal stripes 11 is just equal to a designed length.

In embodiments of the present disclosure, the first frame 21 is made of a shape memory alloy having a shape memory function and used for welding the mask plate. It is only needed to impose a constant force may onto the first frame 21 during the whole assembly process. Specifically, the constant force meets the following condition: a deformation magnitude generated when two opposite ends of the first frame are contracted inward is equal to X % of the design value of the light-shielding metal stripes. Under this circumstance, there is no need to lengthen the mask plate, but only needs to weld the mask plate directly to the first frame 21. After completion of welding and assembling the mask plate, the force that is imposed on the first frame 21 is cancelled and the first frame 21 is heated up to a temperature, which is a phase inversion temperature (PIT) of the shape memory alloy and depends on components of the shape memory alloy. After being heat process, the first frame 21 restores its original shape. In the meantime, as the first frame 21 restores its original shape, the mask plate is lengthened to X % of the deformation magnitude of the design.

Compared with the conventional structure of a frame of a mask plate in the related arts in which stainless steel or an invar alloy has been used, in the mask device provided by embodiments of the present disclosure, a shape memory alloy having a shape memory function is used for the frame (the first frame 21) of the mask plate. Therefore, in the process of welding and assembling mask plate, there is needless to adjust counter force imposed, and a constant force is always imposed on the first frame 21. After completion of welding and assembling the mask plate, the counter force is stopped imposing and the first frame 21 is heated, so as to enable the first frame 21 to restore its original shape before its deformation. The assembly method according to embodiments of the present disclosure can simplify the assembly process for the mask device greatly.

When the mask plate includes a plurality of light-shielding metal stripes, the method according to embodiments of the present disclosure avoids a complicated computation to conduct welding simulation on each of the plurality of light-shielding metal stripes, which reduces error caused by using simplified models and different analyses methods during multiple simulations, thereby keeping each of the plurality of light-shielding metal stripes under similar tension and similar state, and improving a quality of the mask plate. In this way, the assembly method can not only simplify the assembly process for the mask device greatly, but also improve the quality of mask plate, and improve production efficiency and yield, which is significant to actual production and improvement of yield.

The above are merely the preferred embodiments of the present disclosure. It should be appreciated that, a person skilled in the art may make further improvements and modifications without departing from the principle of the present invention, and these improvements and modifications shall also be considered as the scope of the present invention.

What is claimed is:

1. A mask device, comprising:
a frame; and
a mask plate arranged within the frame,
wherein the frame comprises a first frame and a second frame which are fixed together one on another;
the first frame is made of a shape memory alloy;
the second frame is made of a metal material whose thermal expansion coefficient is smaller than a predetermined value; and
the mask plate is welded to the first frame.

2. The mask device according to claim 1, wherein the shape memory alloy is a nickel titanium alloy.

3. The mask device according to claim 1, wherein the second frame is made of stainless steel or an invar alloy.

4. The mask device according to claim 1, wherein the first frame is of a 0.1-10 mm thickness, while the second frame is of a 10-30 mm thickness.

5. The mask device according to claim 1, wherein the first frame and the second frame are provided with pairs of spiral registration holes, through which the first frame and the second frame are fixed to each other by using bolts.

6. The mask device according to claim 1, wherein the mask plate comprises a plurality of light-shielding metal stripes spaced from each other.

7. The mask device according to claim 1, wherein the mask plate is a Fine Metal Mask (FMM) for Organic Light-Emitting Diode (OLED) evaporation.

8. The mask device according to claim 2, wherein the mask plate is an FMM for OLED evaporation.

9. The mask device according to claim 3, wherein the mask plate is an FMM for OLED evaporation.

10. The mask device according to claim 4, wherein the mask plate is an FMM for OLED evaporation.

11. The mask device according to claim 5, wherein the mask plate is an FMM for OLED evaporation.

12. The mask device according to claim 6, wherein the mask plate is an FMM for OLED evaporation.

13. A method for assembling a mask device, comprising:
providing a first frame, which is made of a shape memory alloy;
providing a second frame, which is made of a metal material whose thermal expansion coefficient is smaller than a predetermined value;
imposing a constant force onto two opposite ends of the first frame, so as to enable the two opposite ends of the first frame to be contracted inward and thereby deformed;
welding a mask plate to the first frame;
subsequent to the welding, stopping imposing the constant force onto the two opposite ends of the first frame;
heating the first frame, so as to restore the first frame to be in an original form; and
fixing the first frame welded with the mask plate onto the second frame.

14. The method according to claim 13, wherein the mask plate comprises a plurality of light-shielding metal stripes spaced from each other; and
the step of welding the mask plate to the first frame comprises:
welding two ends of each of the light-shielding metal stripes to two opposite ends of the first frame, respectively.

15. The method according to claim 14, wherein an actual length of the light-shielding metal stripe is X % less than a design value; and
the constant force meets the following condition: a deformation magnitude generated when the two opposite ends of the first frame are contracted inward is equal to X % of the design value of the light-shielding metal stripe.

16. The method according to claim 13, wherein the step of heating the first frame, so as to restore the first frame to be in the original form comprises:
heating the first frame by using hot metal wires.

17. The method according to claim 13, wherein in the step of heating the first frame so as to restore the first frame to be in the original form, the first frame is heated at a temperature of 100-200° C. when the first frame is made of a nickel titanium alloy.
